(19) United States
(12) Patent Application Publication
(10) Pub. No.: US 2019/0115554 A1
(43) Pub. Date: Apr. 18, 2019

(54) Luminescent Device and Display Device Using Same

(71) Applicant: AAC Technologies Pte, Ltd., Singapore city (SG)

(72) Inventor: Zaifeng Xie, Shenzhen (CN)

(21) Appl. No.: 15/955,878

(22) Filed: Apr. 18, 2018

(30) Foreign Application Priority Data
Oct. 13, 2017 (CN) 201710954966.2

(51) Int. Cl. H01L 51/50; H01L 51/56; H01L 51/00; C09K 11/06

(52) U.S. Cl. CPC H01L 51/5028; H01L 51/5004; H01L 51/5016; H01L 51/56; H01L 51/001; H01L 51/0085; H01L 2251/552; H01L 51/0059; H01L 51/0072; C09K 2211/185; C09K 2211/1029; C09K 11/06

(57) ABSTRACT

The invention relates to the field of organic luminescent technology, in particular to a luminescent device and a display device. The luminescent device includes a first electrode, a second electrode and at least a luminescent layer arranged between the first electrode and the second electrode. The luminescent layer includes at least a host material, at least an energy level transition layer material and at least a guest material; the energy level transition layer material can receive the energy of the host material and transfer the energy to the guest material, thus solving the problem where the energy formed on the host material cannot be effectively transferred to the guest material to carry on the high efficiency luminescence during electroluminescence when the difference between the host material T₁ energy and the guest material T₁ energy is large, in order to greatly improve the efficiency of the luminescent device.

### FIELD OF THE PRESENT DISCLOSURE

The invention relates to the field of organic luminescent technology, in particular to a luminescent device and a display device thereof.

### DESCRIPTION OF RELATED ART

A luminescent device—Organic Light-Emitting Diode (OLED) comes into being and gradually enters the field of vision as a new generation of flat panel display technology. OLED is characterized by its own luminescence, unlike the thin-film transistor liquid crystal display (TFT-LCD), which requires backlight, so it has high visibility and brightness, followed by low voltage demand and high power saving efficiency. Coupled with fast reaction, light weight, thin thickness, simple construction and low cost etc, it is regarded as one of the most promising products in 21^{th} century. At present, in the application of mobile phone screen, OLED replacing Liquid Crystal Display (LCD) has become the trend of the times. Some Samsung models of cell phones already use the OLED screen, and Apple Company has announced that all its phones will have OLED screens in 2018.

At the beginning of development, the structure of OLED was very simple, namely anode/luminescent layer (a luminescent material) EML/cathode. The device performance of such device structure is very poor, for example, the turn on voltage needs 14V. This is because, in general, the HOMO and LUMO of the luminescent material are very mismatched with the anode or cathode, resulting in difficulties in the hole or electron injection, and therefore, a very high turn on voltage is required. In addition, the luminescent layer EML has only one kind of luminescent material. In the electroluminescence process, the exciton concentration of the luminescence is very high, which leads to the quenching of the exciton, resulting in very low luminescence efficiency. For the application of OLED display or lighting, the device structure like this needs to be improved, especially for low turn on voltage, high luminescent efficiency, high quantum efficiency and long lifetime.

For this reason, a lot of improved device structures are proposed, and the two common techniques are multilayer structure and host-guest doping system. For example, the basic device structure of the present OLED is an anode/hole injection layer (HILL)/a hole transport layer (HTL)/a luminescent layer (EML)/an electron transport layer (ETL)/an electron injection layer (EIL)/a cathode. In such devices, each functional layer is responsible for a single function, leading to a great improvement in the performance of OLED. For example, HIL is a kind of hole injection, which reduces the barrier between the anode and HTL hole transport layer and reduces the turn on voltage; EIL is an electron injection layer that reduces the barrier between the cathode and the ETL electron transport layer and makes it more matched. EML adopts the host and guest doped system, and the holes injected from the anode and the electrons injected from the cathode combine on the host material and form triplet and singlet excitons. In this way, the excitons are transferred to the triplet or the singlet of the guest material. When the energy is obtained from the triplet or the singlet of the guest material, the excitons need to be excited by photoluminescence due to its instability. This multilayer device structure significantly improves the performance of OLED. However, the traditional OLED structure needs to be further improved in terms of reducing the turn on voltage, improving the luminescent efficiency of OLED and prolonging the lifetime of OLED etc.

In a traditional OLED device, there is a host material and a guest material, and its energy transfer diagram is shown in FIG. 1, in which K_{F} represents the process of energy transfer from host to guest, and K_{R} represents the process of energy transfer from guest to host, ΔE=T_{1,H}−T_{1,G}. The energy transfer processes between host and guest materials are as follows:

(1) ΔE is much larger than 0. The host material energy level T_{1,H} is much larger than the guest material's energy level T_{1,G}, and even the K_{F} is much larger than K_{R}, so that both cannot produce energy resonance, therefore, in the process of electroluminescence, the energy formed on the host material cannot be effectively transferred to the host material for efficient luminescence.

(2) ΔE>0. This is the most ideal energy transfer system. In this device structure K_{F}>K_{R}, there is an effective energy resonance between the host material and the guest material, so a good host and guest energy transfer process can take place.

(3) ΔE<0. In this system, when the energy level of the guest is higher than that of the host material, K_{F}<K_{R}, this will lead to the fact that the partial energy is transferred to the host material from the guest material, thus the energy inversion will occur.

(4) ΔE is much less than 0. In this system, K_{F} is much less than K_{R}. In this case, the energy of the system will be transferred from the guest to the host material, thus the triplet energy quenching process will take place.

The concentration quenching of excitons in the luminescent layer is an important factor to reduce the performance of OLED devices. The main types of exciton quenching are triplet-triplet annihilation (STA), triplet-polar annihilation (TTA) and singlet-triplet annihilation (TPA). TTA and TPA mainly occur in phosphorescent OLED devices. STA mainly occurs in fluorescent OLED devices.

However, whether phosphorescence OLED or fluorescence OLED, too much exciton density (doping concentration is too high) will often lead to the above phenomenon, but if the doping concentration is reduced, the energy transfer between host and guest will be incomplete, and the device efficiency will also be reduced. In order to further improve the luminescent efficiency of OLED devices, the technicians need to use optical extraction technology outside the OLED devices, which is to extract the light from the OLED devices to the outside of the devices as much as possible. This technique often requires scattering method layer or micro-lens arrays to fabricate or attach the scattering layer outside the device. This will increase the complexity of the OLED manufacturing process and increase the production costs.

### BRIEF DESCRIPTION OF THE DRAWINGS

Many aspects of the exemplary embodiments can be better understood with reference to the following drawings. The components in the drawing are not necessarily drawn to scale, the emphasis instead being placed upon clearly illustrating the principles of the present disclosure.

FIG. 1 is a schematic diagram of energy transfer in the traditional OLED devices;

FIG. 2 is a schematic diagram of the structure of the luminescent device of an embodiment of the present invention;

FIG. 3 is a schematic diagram of the structure of the display device of the embodiment of the present invention;

FIG. 4 is a schematic diagram of the energy transfer of a luminescent device according to an embodiment of the present invention;

FIG. 5 is a schematic diagram of energy transfer of another luminescent device in the embodiment of the present invention;

FIG. 6 is a schematic diagram of the light-oriented guest material of the embodiment of the present invention;

FIG. 7 is a schematic diagram of an light-oriented guest material testing system of the embodiment of the present invention;

FIG. 8 is a diagram of the energy level structure of the embodiment of the present invention.

FIG. 9 is a spectral diagram of a host material an energy level transition layer material and an light-oriented guest material in an 1# luminescent layer of an embodiment of the present invention.

Of which:
1—photoluminescence spectra of a host material;
2—photoluminescence spectra of an energy level transition layer material;
3—photoluminescence spectra of a guest material;
4—ultraviolet absorption spectra of an energy level transition layer material;
5—UV absorption spectra of guest material;
10—luminescent device;
11—first electrode;
12—hole transport layer;
13—luminescent layer;
14—electronic transport layer;
15—second electrode;
16—substrate;
100—polarizing film;
200—ellipsometer.

### DETAILED DESCRIPTION OF THE EXEMPLARY EMBODIMENTS

The present disclosure will hereinafter be described in detail with reference to several exemplary embodiments. To make the technical problems to be solved, technical solutions and beneficial effects of the present disclosure more apparent, the present disclosure is described in further detail together with the figure and the embodiments. It should be understood the specific embodiments described hereby is only to explain the disclosure, not intended to limit the disclosure.

The present invention is further elaborated in combination with exemplary embodiments. It should be understood that these embodiments are used only to illustrate the invention and not to limit the scope in the invention.

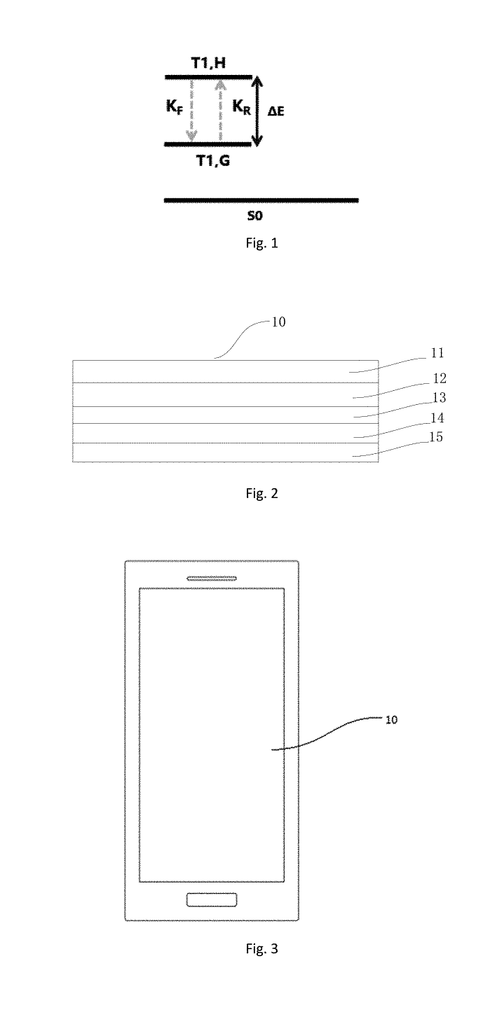

The embodiment of the invention proposes a luminescent device 10, the structure of which is illustrated in FIG. 2, comprising a first electrode 11, a second electrode 15 and at least a luminescent layer 13 arranged between the first electrode 11 and the second electrode 15; The invention also comprises a hole transport layer 12 and an electron transport layer 14 relative to the hole transport layer 12, and the hole transport layer 12 and the electron transport layer 14 are arranged between the first electrode 11 and the second electrode 15; The luminescent organic layer 13 is arranged between the hole transport layer 12 and the electron transport layer 14.

The embodiment of the invention also relates to a display device, including a luminescent device 10 of the present invention as shown in FIG. 3.

The luminescent layer of the luminescent device for the embodiment of the invention comprises at least a host material, at least an energy level transition layer material and at least a guest material; the energy level transition layer material can receive the energy of the host material and transfer the energy to the guest material, which can capture the exciton of the host material and transfer the obtained exciton efficiently to the light-oriented guest material. Therefore, the defect mentioned in background technology that the energy formed on the host material cannot be effectively transferred to the guest material for high efficiency luminescence when E is far greater than 0:00 during electroluminescence process, is solved. Thus, the luminescent efficiency of the luminescent device is improved.

Further optionally, the energy level transition layer material can not only directly accept the energy of the host material, but also capture the energy lost during the energy transfer from the host material to the guest material. That is to capture the exciton energy which is used to transfer from the host material to the light-oriented guest material, thus greatly improving the luminescent efficiency of the luminescent device.

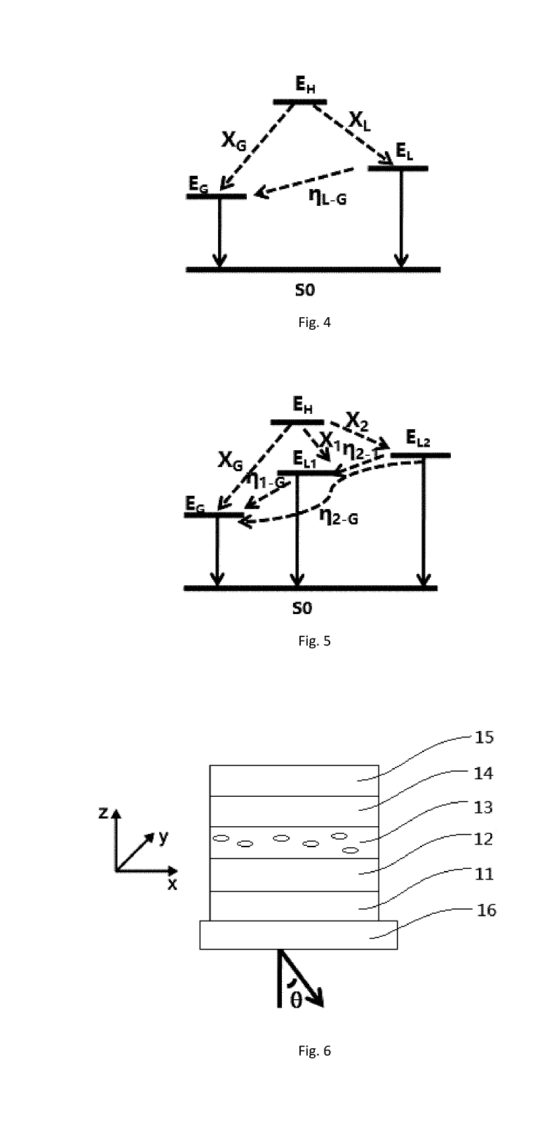

The energy transfer schematic of the luminescent device of the embodiment of the present invention is shown in FIG. 4. Among them, X_{G} represents the proportion of exciton energy the guest material (G) obtains from the host material (H), and XL represents the proportion of exciton energy the energy transition layer material obtains from the host material, and η_{L-G} represents the energy transfer efficiency from the energy transition layer material to the guest luminescent material, E_{H} represents the energy level of the host material, E_{G} represents the energy level of the light-oriented guest material, E_{L} represents the energy level of the energy transition layer and S₀ represents the energy level of the ground state.

The final external quantum efficiency of the luminescent device can be expressed as follows:

ηₑₓₜ=γη_{oc}{i_{G}χ_{G}ϕ_{PL,G}+(1−η_{L-G})ϕ_{PL,L}}

Among them, ηₑₓₜ represents the external quantum efficiency of the luminescent device, γ represents the charge balance coefficient, and η_{oc} represents the light extraction efficiency, i represents the decrease proportion of the excitons formed by electroluminescence being captured by the luminescent material, and Φ_{P}_{_{L}} represents the absolute quantum efficiency of the material.

If there are two energy transition layers in the EML layer, that is, a host material, a first energy level transition layer material E_{L1}, a second energy level transition layer material E_{L2}, and a light-oriented guest material E_{G}. Its energy transfer diagram is shown in FIG. 5.

Because the energy level between the traditional host material and the guest material is too large in the traditional luminescent devices, even if the absorption spectra and photoluminescence spectra of the two have better overlapping characteristics. In the process of electroluminescence, the energy formed on the host material cannot be completely transferred to the guest material, resulting in energy loss. Because there is only a guest material and a host material in the traditional luminescent devices, the number of excitons in the photoluminescence layer increases rapidly and the exciton density is too high when the luminance is high (or driven by high current). The quenching mechanisms such as STA, TTA, and TPA etc are induced, and obvious efficiency roll-off is observed.

From the energy transfer diagram shown in FIGS. 4 and 5, it can be seen that at least an energy level transition layer material is denoted by L₁, L₂, . . . Ln, and n is an integer greater than or equal to 1, and the triplet energy level of the host material is T_{1,H}, the triplet energy level of the energy level transition layer material is T_{1, Ln}, and the triplet energy level of the guest material is T_{1,G}; T_{1,H}, T_{1,Ln}, T_{1,G} meet: T_{1,H}>T_{1,Ln}>T_{1,G}.

When the host material, the energy level transition layer material are selected from the fluorescent material or the thermal delay fluorescent material; the singlet energy level of the host material is S_{1,H}, and the singlet energy level of the energy level transition layer material is S_{1,Ln}, S_{1,H}, S_{1,Ln} meet: S_{1,H}>S_{1,Ln};

When the energy level transition layer material, the guest material are selected from the fluorescent material or the thermal delay fluorescent material; the singlet energy level of the energy level transition layer material is S_{1, Ln}, and the singlet energy level of the guest material is S_{1,G}; S_{1,Ln}, S_{1,G} meet: S_{1,Ln}>S_{1,G};

When the host material and the guest material are selected from the fluorescent material or the thermal delay fluorescent material; the singlet energy level of the host material is S_{1,H}, and the singlet energy level of the guest material is S_{1,G}; S_{1,H}, S_{1,G} meet: S_{1,H}>S_{1,G};

When the host material, the energy level transition layer material and the guest material are selected from the fluorescence material or the thermal delayed fluorescence material, the singlet energy level of the host material is S_{1,H}, and the singlet energy level of the energy level transition layer material is S_{1, Ln}, and the singlet energy level of the guest material is S_{1,G}; S_{1,H}, S_{1, Ln}, S_{1,G} meet: S_{1,H}>S_{1,Ln}>S_{1,G}.

Moreover, the luminescent layer of the embodiment in the invention simultaneously contains the three types of materials, that is, the three types of materials are blended to prepare the luminescent layer, and the energy level transition layer material and the host material are uniformly doped in the luminescent layer. In other words, each guest material molecule is surrounded by the host material or the energy level transition layer material molecule, which can reduce the contact chance of the guest material at high current and improve the exciton quenching phenomenon.

The luminescent device of the embodiment in the present invention is further illustrated from a spectral point of view.

In the embodiment of the invention, the photoluminescence spectrum of the host material of the luminescent device is PL_{H}, and the photoluminescence spectrum of the energy level transition layer material is PL_{Ln}. The main emission peak of PL_{H} and the emission peak of PL_{Ln} meet: the wavelength of the main emission peak of PL_{H}<wavelength of the main emission peak of PL_{Ln}.

Further optionally, the wavelength of the main emission peak of 380 nm<PL_{H} is less than the wavelength of the main peak of PL_{Ln}<800 nm. When PL_{H} and PL_{Ln} are closer, the energy conversion rate is higher. The wavelength of the main emission peak of PL_{H} is not exactly the same as that of the main peak of PL_{Ln}, or the difference is less than 1 nm, because the difference between the main peaks is smaller, the energy transfer on both sides of the main peak is not guaranteed to be the best. Therefore, the wavelength of the main emission peak of PL_{H} is at least 1 nm smaller than that of the main emission peak of PL_{Ln}.

Further optionally, the difference between the wavelength of the emission main peak of PL_{H} and the wavelength of the main emission peak of PL_{Ln} is 1˜200 nm.

Further optionally, the wavelength of the emission main peak of PL_{H} is at least 50 nm smaller than that of the main emission peak of PL_{Ln}. That is, the difference between the wavelength of the main emission peak of PL_{H} and that of the emission peak of PL_{Ln} is 50˜200 nm. If the difference between the two is too large, the energy conversion efficiency is too low, the two are too close, the energy transfer is also affected, and there may be energy reversal.

The photoluminescence spectrum of the guest material from the luminescent device of the embodiment of the invention is PL_{G}. The main emission peaks of PL_{H} and the emission peak of PL_{Ln} meet: the wavelength of the main emission peak of PL_{Ln}<the wavelength of the main emission peak of PL_{G}.

Further optionally, 380 nm<the wavelength of the main emission peak of PL_{Ln}<the wavelength of the main peak of PL_{G}<800 nm.

Further optionally, the wavelength of the emission main peak of PL_{Ln} is at least 1 nm smaller than that of the main emission peak of PL_{G}.

Further optionally, the difference between the wavelength of the emission main peak of PL_{Ln} and the wavelength of the main emission peak of PL_{G} is 1˜200 nm.

Further optionally, the wavelength of the emission main peak of PL_{Ln} is at least 5 nm smaller than that of the main emission peak of PL_{G}. That is, the difference between the wavelength of the main emission peak of PL_{Ln} and that of the emission peak of PL_{G} is 5˜200 nm.

In the embodiment of the invention, the wavelength of emission main peak of the host material in the luminescent device is smaller than that of the energy level transition layer material, and the wavelength of the emission main peak of the energy level transition layer material is smaller than wavelength of the emission main peak of the guest material.

Moreover, the photoluminescence spectra of the host material of the luminescent device from the embodiment of the invention has very good spectral overlap with the ultraviolet absorption spectra of the energy level transition layer and the ultraviolet absorption spectra of the host material, respectively.

In the embodiment of the invention, the photoluminescence spectrum of the host material of the luminescent device is PL_{H}, the photoluminescence spectrum of the energy level transition layer material is PL_{Ln}, and the UV absorption spectrum of the guest material is Abs_{G} and the UV absorption spectrum of the energy level transition layer is Abs_{Ln};

Abs_{G}−PL_{H} denotes a spectral overlap region between Abs_{G} and PL_{H}, and FL_{G}−PL_{Ln} denotes the spectral overlap region between Abs_{G} and PL_{Ln}: Abs_{G}−PL_{H}>Abs_{G}−PL_{Ln}.

Abs_{Ln}−PL_{H} denotes a spectral overlap region between Abs_{Ln} and PL_{H}: Abs_{Ln}−PL_{H}>0.

The overlapping region between UV absorption spectra of guest materials and photoluminescence spectra of host materials is larger than that of ultraviolet absorption spectra of guest materials and photoluminescence spectra of transition layer materials.

The luminescent device of the embodiment of the invention is further illustrated from the materials below.

Further optionally, the guest material of the embodiment in the present invention is a light-oriented luminescent material (referred to as light-oriented guest material). That is, the luminescent material with light orientation is a material with the ratio of light output in the direction perpendicular to the transition dipole moment of the luminescent material is larger than that in the transition dipole moment in parallel with the luminescent material.

The molecules of each luminescent material in the luminescent layer can be considered as an oscillating dipole. When the direction of the light is perpendicular to the direction of dipole moment, the light can escape more; when the direction of the light is parallel to the direction of the dipole moment, the intensity of the light will decrease obviously. For the luminescent devices, the dipole moment direction of a luminescent oscillator has a great influence on the output intensity of the parasitic waveguide mode (PWM). Therefore, the most direct way to improve the output efficiency of OLED is to make the transition dipole moment (TDM) of the luminescent molecules of a luminescent device parallel to its light output direction, that is to say, in the actual luminescent devices, the transition dipole moment (TDM) of the luminescent molecules is required to be parallel to the direction of the ITO substrate.

The schematic diagram of the light-oriented guest material is shown in FIG. 6. In FIG. 6, a first electrode 11 is a cathode, and a second electrode 12 is an anode. In the luminescent layer 13, an ellipse represents a guest material, and the guest material is dispersed in a host material, and X and Y axis is a direction parallel to the substrate, and Z axis is a direction perpendicular to the substrate.

For a single luminescent molecule, its transition dipole moment (TDM) is P=(Px,Py,Pz). In order to evaluate the angle between the transition dipole moment of each luminescent molecule and the direction of the substrate, an angle factor θ is introduced, and θ meets:

$$θ = \frac{{\sum }_{i = 1}^{n} {a}_{i} {p}_{z , i}^{2}}{{\sum }_{i = 1}^{n} {a}_{i} {p}_{i}^{2}} , {\sum }_{i = 1}^{n} {a}_{i} = 1.$$

Where, ai is a contribution coefficient of the transition dipole moment (TDM) in each direction.

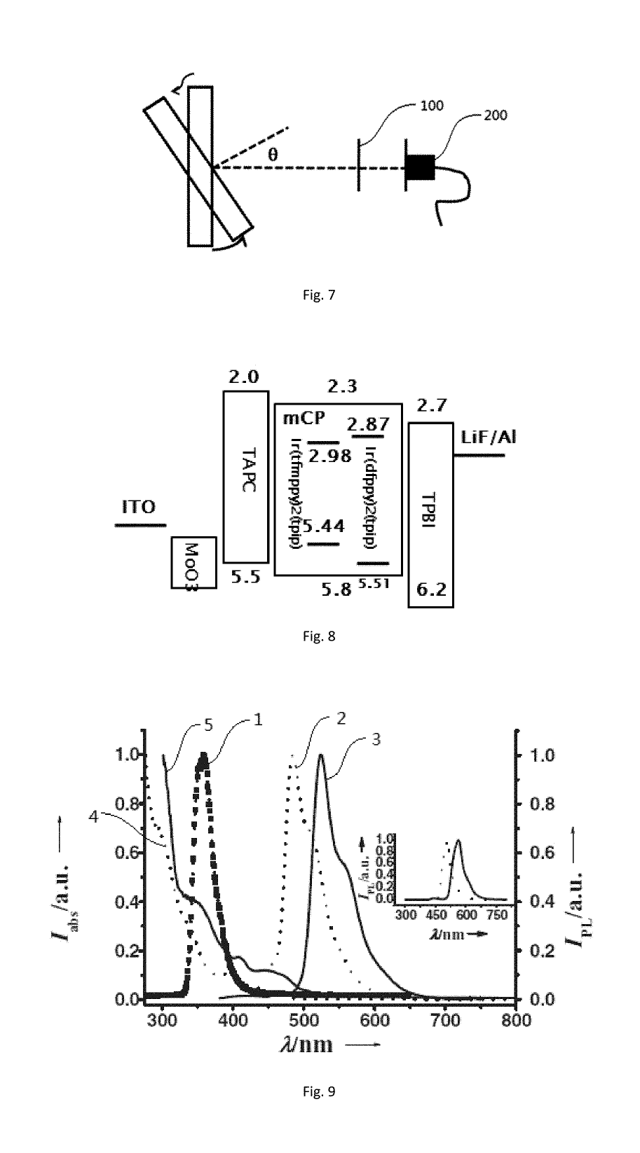

An angle-resolved spectroscopy (SMS-500) or a time-resolved spectroscopy is used for evaluating the test equipment. The test system is shown in FIG. 7.

In order to further evaluate the relative size of dipole moment, a theoretical simulation is carried out with reference to the classical green light material Ir(ppy)₃, according to the following formula:

$$U ( μ , r ) ∝ - \frac{{μ}^{2}}{{r}^{3}} .$$

Where, U is a dipole-dipole moment, μ is a dipole moment, r is a molecular radius. According to the theoretical simulation, the simulation calculation is carried out by using Gaussian 09 software and DFT method at B3LYP/LANL2DZ level. The data of some light-oriented guest materials are obtained as shown in Table 1.

TABLE 1

| Light-oriented | | | | | | |
|---|---|---|---|---|---|---|
| guest material | T₁(eV) | r(A) | μ(D) | U | θ | U/U_{Ir(ppy)3} |
| Ir(ppy)₃ | 2.43 | 11.95 | 6.31 | 0.023 | 0.33 | 1.00 |
| Ir(ppy)₂(acac) | 2.36 | 11.82 | 2.19 | 0.003 | 0.24 | 0.12 |
| Ir(bppo)₂(acac) | 2.34 | 11.98 | 6.21 | 0.022 | 0.22 | 0.96 |
| Ir(bppo)₂(ppy) | 2.28 | 11.99 | 8.37 | 0.041 | 0.33 | 1.74 |
| Ir(ppy)₂(bppo) | 2.18 | 11.97 | 8.29 | 0.040 | 0.32 | 1.72 |
| Ir(chpy)₃ | 2.31 | 11.6 | 2.02 | 0.002 | 0.23 | 0.09 |
| Ir(BT)₂(acac) | 2.20 | 12.6 | 1.76 | 0.001 | 0.22 | 0.05 |
| Ir(MDQ)₂(acac) | 2.00 | 13.8 | 1.75 | 0.0008 | 0.24 | 0.04 |
| Ir(piq)₃ | 1.94 | 13.5 | 5.2 | 0.009 | 0.22 | 0.39 |
| Ir(tfmppy)₂(tpip) | 2.37 | 11.56 | 8.25 | 0.041 | 0.21 | 1.12 |

Where, some of the chemical structures are as follows:

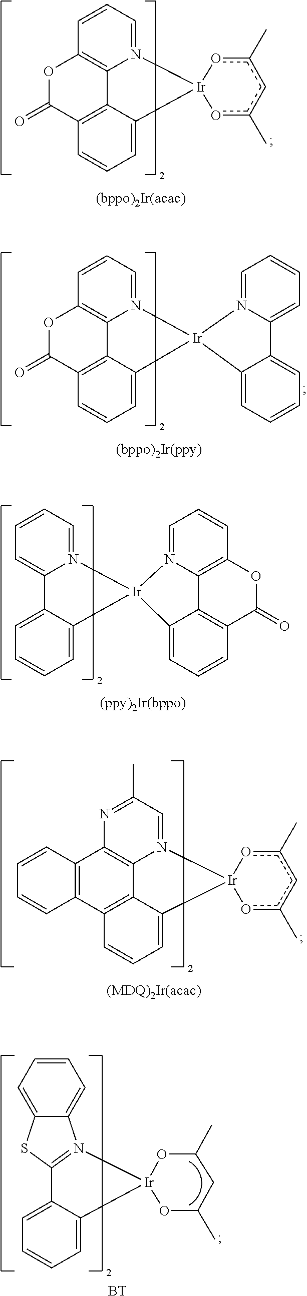

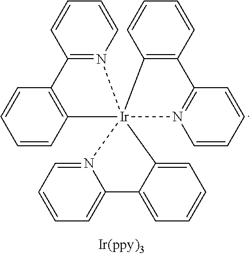

Optionally, an energy level transition layer material may be a phosphorescent material, a fluorescent material or a thermal delayed fluorescence material. Further optionally, the energy level transition layer material is a phosphorescent material.

Further optionally, the mass percentage content of the transition layer material in the luminescent layer is 1%˜30%. The doping amount of the transition layer can be selected according to the specific requirements of the device. Specifically, the upper doping limit of the energy level transition layer material can be 30%, 28%, 25%, 20%, 15%, 10% of the total mass of the luminescent layer. The lower doping limit of the energy level transition layer can be 1%, 2%, 5%, 8%, 9% of the total mass of the luminescent layer. The range of mass percentage content of the energy level transition layer material in the luminescent layer can be composed of the above values.

Optionally, when n energy level transition layer materials are arranged in the luminescent layer, the mass sum of the n level transition layer materials shall not exceed 50% of a host material.

Optionally, the guest material may be a phosphorescent material, a fluorescent material or a thermal delayed fluorescent material.

Further optionally, the guest material is phosphorescent material.

Further optionally, the mass percentage content of the guest material in the luminescent layer is 1%˜20%. The doping amount of the guest material in the luminescent layer can be selected according to the specific requirements of the device. In particular, the upper doping limit of the host material may be 20%, 18%, 15%, 12%, 10%, 5% of the total mass of the luminescent layer. The lower doping limit of the guest material can be 1%, 2%, 3%, 4%, 4.5% of the total mass of the luminescent layer. The range of mass percentage content of the host material in the luminescent layer may be composed of the above values.

The contents of the embodiment of the invention are further explained below in a specific manner. In the following specific embodiments, the following host material, guest material and energy level transition layer material may be selected as an example, without limiting the contents of the embodiment of the present invention. According to the content introduced by the embodiment of the invention, other kinds of materials may be selected to prepare a luminescent device having the effect of the embodiment of the invention. In order to explain the technical advantages of the invention and the principle of the device, the invention is only illustrated by the simplest device structure.

Device Fabrication

The ITO substrate is a 30 mm×30 mm bottom emitting glass with four luminescent regions, covering a luminescent area of 2 mm×2 mm, and a transmittance of ITO thin film is 90%@550 nm, and its surface roughness Ra<1 nm, and its thickness is 1300 A, with square resistance of 10 ohms per square meters.

The cleaning method of ITO substrate as follows: first it is placed in a container filled with acetone solution, and the container is placed in ultrasonic cleaning machine for 30 minutes, in order to dissolve and remove most of the organic matter attached to the surface of ITO; and then the cleaned ITO substrate is removed and placed on the hot plate for half an hour at high temperature of 120° C., in order to remove most of the organic solvent and water vapor from the surface of the ITO substrate; and then the baked ITO substrate is transferred to the UV-ZONE equipment for processing with O³ Plasma, and the organic matter or foreign body which could not be removed on the ITO surface is further processed by plasma, and the processing time is 15 minutes, and the finished ITO is quickly transferred to the film forming chamber of the OLED evaporation equipment.

OLED preparation before evaporation: first of all, the OLED evaporation equipment is prepared, and then IPA is used to wipe the inner wall of the chamber, in order to ensure that the whole film chamber is free of foreign bodies or dust. Then, the crucible containing OLED organic material and the crucible containing aluminum particles are placed on the position of organic evaporation source and inorganic evaporation source in turn. By closing the cavity and taking the initial vacuum and high vacuum, the internal evaporation degree of OLED evaporation equipment can reach 10 E⁻⁷ Torr.

OLED evaporation film: the OLED organic evaporation source is opened to preheat the OLED organic material at 100° C. for 15 minutes to ensure the further removal of water vapor from the OLED organic material. Then the organic material that needs to be evaporated is heated rapidly and the baffle over the evaporation source is opened until the evaporation source of the material runs out and the wafer detector detects the evaporation rate, and then the temperature rises slowly, the temperature rise is 1˜5° C., until the evaporation rate is stable at 1 A/s, the baffle directly below the mask plate is opened and the OLED film is formed. When it is observed that the organic film on the ITO substrate reaches the preset film thickness at the computer end, the mask baffle and the evaporative source directly above the baffle are closed, and the evaporative source heater of the organic material is closed. The evaporation process for other organic and cathode metal materials is described above. When evaporating the host material and auxiliary material in the luminescent layer, the solid film of exciplex is formed by controlling the evaporation rate of the host material and auxiliary material.

OLED encapsulation process: the cleaning and processing of 20 mm×20 mm encapsulation cover is as the same as the pretreatment of ITO substrate. The UV adhesive coating or dispensing is carried out around the epitaxial of the cleaned encapsulation cover, and then the encapsulation cover of the finished UV adhesive is transferred to the vacuum bonding device, and stuck with the ITO substrate of the OLED film in vacuum, and then transferred to the UV curing cavity for UV-light curing at wavelength of 365 nm. The light-cured ITO devices also need to undergo post-heat treatment at 80° C. for half an hour, so that the UV adhesive material can be cured completely.

### Embodiment 1

To construct the multilayer device structure of ITO/HIL/HTL/step photoluminescence layer/ETL/EIL/cathode, the chemical structure of some organic materials is as follows:

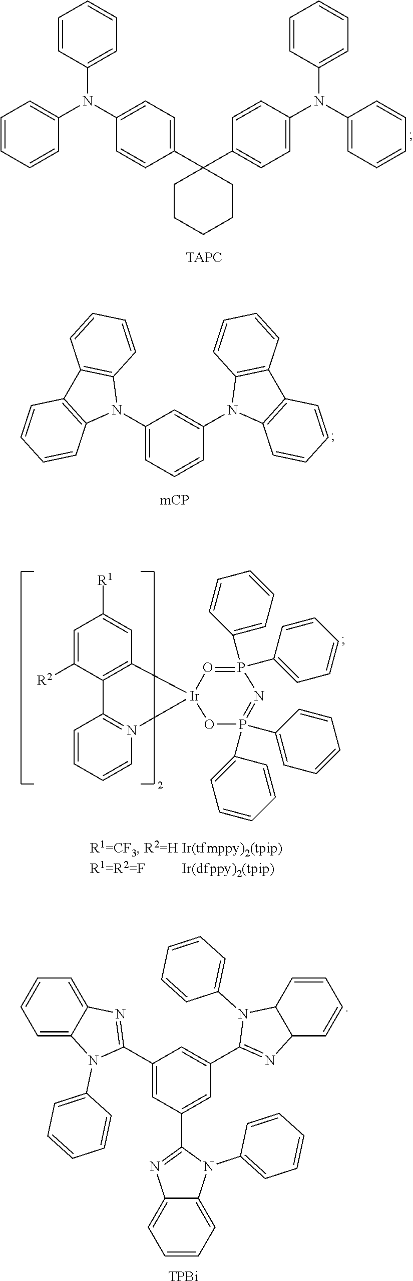

Among them, MoO₃ is used as a hole injection layer material, TAPC is used as a hole transport layer material, and mCP is used as a host material. Ir(dfppy)₂/(tpip) is used as an energy level transition layer material, and a doping amount is 15 wt. %, Ir(tfmppy)₂/(tpip) is used as a green light oriented guest material, and a doping amount is 5 wt. %. TPBI is used as an electron transport layer and a hole barrier material, and LiF is as an electron injection layer material and Al is used as a cathode. Ir(tfmppy)₂(tpip) is a heterocyclic ligand metal chelate with large vertical transition dipole moment DVT that can be used as a light-oriented guest material.

Analysis of energy level and spectral characteristics:

The triplet energy level of TAPC T=2.87 eV, and the triplet energy level of TPBi T₁=2.74 eV;

The triplet energy level of mCP T₁=2.9 eV;

The triplet energy level of the energy level transition layer material Ir(dfppy)₂(tpip) T₁=2.54 eV;

The triplet energy level of the light-oriented guest material Ir(tfmppy)₂(tpip) T_{1,}=2.36 eV;

T_{1,H}>T_{1,Ln}>T_{1,G} is satisfied.

Therefore, the triplet T1 energy level in the hole transport layer and the electron transport layer is higher than that of the host material, the energy level transition layer material and the guest material. Therefore, the electrically induced excitons can be strictly confined to the EML layer.

The energy level structure of the device is shown in FIG. 8. According to FIG. 8, the energy levels of HOMO and LUMO are 5.5 eV and 2.0 eV, respectively. The energy levels of HOMO and LUMO of TPBi are 6.2 eV and 2.7 eV, respectively. The energy levels of HOMO and LUMO of the host material mCP are 5.8 eV and 2.3 eV, respectively. The energy levels of HOMO and LUMO of Ir(dfppy)₂(tpip) are 5.51 eV and 2.87 eV, respectively. The HOMO and LUMO energy levels of the light-oriented guest material Ir(tfmppy)₂(tpip) are 5.44 eV and 2.98 eV, respectively.

The spectral diagram of the above host material, the energy level transition layer material and the light-oriented guest material is shown in FIG. 9: where, 1 is a photoluminescence spectrum of the host material, 2 is the photoluminescence spectrum of the energy level transition layer material, 3 is the photoluminescence spectrum of the guest material, 4 is the ultraviolet absorption spectrum of the energy level transition layer material, and 5 is the ultraviolet absorption spectrum of the guest material. According to analysis of FIG. 9:

(1) The emission peak wavelength of the photoluminescence spectrum 1 of the host material is smaller than that of the photoluminescence spectrum 2 of the energy level transition layer. The emission peak wavelength of the photoluminescence spectrum 2 of the transition layer is smaller than that of the photoluminescence spectrum 3 of the host material.

(2) The photoluminescence spectra 1 of the host material and the absorption spectra 4 of the energy level transition layer have very good spectral overlap.

(3) The photoluminescence spectra 1 of the host material and the absorption spectra 5 of the light-oriented guest material have very good spectral overlap.

(4) The absorption spectrum 5 of the host material and the photoluminescence spectrum 1 of the host material share more overlapping region than the overlapping region shared by the absorption spectrum 5 of the guest material and the photoluminescence spectrum 2 of the energy level transition layer material.

(5) The spectral overlapping region between the UV absorption spectrum 4 of the energy level transition layer material and the photoluminescence spectrum 1 of the host material is >0.

Testing of Device Performance:

1. The multilayer device structure of 1#: ITO/HIL/HTL/step light-oriented luminescence layer/ETL/EIL/cathode is constructed:

ITO/MoO₃(10 nm)/TAPC(30 nm)/mCP:Ir(dfppy)₂(tpip):Ir(tfmppy)₂(tpip), 15 wt. %, 5 wt. %, (30 nm)/TPBi(30 nm)/LiF(1 nm)/Al.

The turn on voltage, maximum external quantum efficiency and efficiency roll-off of the encapsulated OLED devices are tested. The experimental results are shown in Table 2.

2. In order to compare the technical advantages of the device 1#, a comparison device R1 # is designed. The structure of the device as follows: ITO/MoO₃(10 nm)/TAPC(30 nm)/mCP:Ir(tfmppy)₂(tpip) 5 wt. %, (30 nm)/TP Bi(30 nm)/LiF(1 nm)/Al.

The comparison R1# is a traditional device structure with a single host-guest doping system. The turn on voltage, maximum external quantum efficiency and efficiency roll-off of the encapsulated OLED devices are tested. The experimental results are also shown in Table 2.

The testing methods are as follows: the experimental data of the turn on voltage, external quantum efficiency and efficiency roll-off are measured using McScience M6100 and M6000 equipment (performance change rate from 0.1 mA/cm2 to 100 mA/cm2).

TABLE 2

| | | Maximum | |
|---|---|---|---|
| | | external | |
| | Turn on | quantum | |
| Device | voltage | efficiency | Efficiency |
| number | (V) | EQE | roll-off |
| 1# | 3.5 | 21.7% | 10% |
| R1# | 3.5 | 17.5% | 30% |

Table 2 shows that the performance of the traditional OLED device is not as good as that of the step light-oriented device of the embodiment of the invention.

This is because the energy level between the host material mCP and the guest material (or light-oriented guest material) is too large. The energy formed on the host material during the electroluminescence process cannot be completely transferred to the guest material (or light-oriented guest material) (even though the absorption spectra and photoluminescence spectra of the two have better overlapping characteristics), thus resulting in a waste of energy. At the same time, because there is only a guest material and a host material in the traditional luminescent devices, the number of excitons of the guest in the luminescent layer increases rapidly when the luminance is high (or driven by high current), and the exciton density is too large, which leads to quenching mechanisms such as STA, TTA, TPA etc, therefore, there is an obvious efficiency roll-off observed.

The energy step light-oriented device structure of the embodiment of the invention has a step type energy level transition layer material, which can capture the excitons of the host material and transfer the obtained excitons to the light-oriented guest material with high efficiency. At the same time, the step energy level transition layer material also has the exciton energy which is consumed by the transfer from the host material to the light-oriented guest material. Furthermore, because of the energy level step light-oriented device structure of the embodiment of the invention, each light-oriented guest material molecule is surrounded by the host material or by the step energy level transition layer material molecule. It can reduce the contact chance of the guest material at high current and improve the exciton quenching phenomenon. Through the above mechanism, the luminescence efficiency of the luminescent device can be significantly improved, and the phenomenon of efficiency rollout can be significantly improved.

### Embodiment 2

The multilayer device structure of ITO/HIL/HTL/step light-oriented photoluminescence layer and ETL/EIL/cathode is constructed. The chemical structure of some of the organic materials used is as follows:

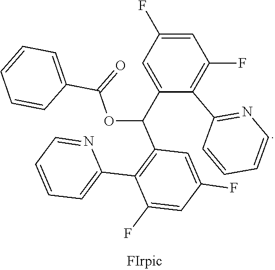 [SMILES: O=C(OC(c1cc(F)cc(F)c1-c1ccccn1)c1cc(F)cc(F)c1-c1ccccn1)c1ccccc1]

In green or yellowish-green devices, mCP is used as the host material, FIrpic is used as the transition layer material, and the green or yellow light light-oriented guest materials are taken from Ir(ppy)₃, Ir(ppy)₂(acac), Ir(bppo)₂(acac), Ir(chpy)₃, Ir(bppo)₂(ppy). The properties of the light-oriented guest materials are shown in Table 1.

Analysis of energy level and spectral characteristics:

The triplet energy level of the host material mCP T₁=2.9 eV;

The triplet energy levels of the energy level transition layer FIrpic are higher than T1 energy level of green or yellowish-green light oriented guest materials (as shown in Table 1).

According to the spectral data of the above host material, the energy level transition layer material and the light-oriented guest material:

(1) The photoluminescence spectra of the host material mCP (main peak 370 nm) are less than that of the energy level transition layer (main peak 475 nm). The photoluminescence peak wavelength of the transition layer is less than that of the photoluminescence spectrum of the light-oriented guest material (scope of main peak 500 nm-560 nm).

(2) The photoluminescence spectra of the host material mCP and the absorption spectra of the energy level transition layer FIrpic have very good spectral overlap.

(3) The photoluminescence spectra of the host material mCP have very good spectral overlap with the absorption spectra of the green or yellowish-green light-oriented guest materials (UV absorption wavelengths of the two are less than 550 nm).

(4) The overlapping region between the absorption spectra of green or yellowish green light-oriented guest materials (UV absorption wavelength of the two is less than 550 nm) and photoluminescence spectra of host materials (the main peak position is about 370 nm) is larger than that of the absorption spectrum of the light-oriented guest material and the photoluminescence spectrum of the energy level transition layer material FIrpic (the main peak position 475 nm).

(5) The overlapping region between UV absorption spectra of the energy level transition layer and photoluminescence spectra of the host material >0.

Testing of Device Performance:

1. Device 2#˜6# is constructed:

ITO/Buffer layer(30 nm/MoO₃(10 nm)/TAPC(30 nm)/mCP:FIrpic: green or yellowish green light-oriented guest material, 15 wt. %, 5 wt. %, (30 nm)/TPB430 nm)/LiF(1 nm)/Al. Among them, the buffer layer uses PEDOT: PSS forms a flat organic conductive layer on ITO.

The turn on voltage, maximum external quantum efficiency and efficiency roll-off of the encapsulated OLED devices are tested. The experimental results are shown in Table 3.

2. In order to compare the technical advantages of the device 2#, a comparison device R2 # is designed. The structure of the device as follows: ITO/Buffer layer/MoO₃ (10 nm)/TAPC(30 nm)/mCP:Ir(ppy)₃/TPBi(30 nm)/LiF(1 nm)/cathode.

The comparison R2# is a traditional device structure with a single host-guest doping system. The turn on voltage, maximum external quantum efficiency and efficiency roll-off of the encapsulated OLED devices are tested. The experimental results are also shown in Table 3.

TABLE 3

| | | | Maximum | |
|---|---|---|---|---|
| | | | external | |
| | | Turn on | quantum | |
| Device | Guest | voltage | efficiency | Efficiency |
| number | material | (V) | EQE | roll-off |
| 2# | Ir(ppy)₃ | 3.8 | 19.7% | 12.6% |
| 3# | Ir(ppy)₂(acac) | 3.4 | 13.4% | 18% |
| 4# | Ir(bppo)₂(acac) | 3.4 | 18.5% | 13.3% |
| 5# | Ir(chpy)₃ | 4.0 | 14.8% | 21.4% |
| 6# | Ir(bppo)₂(ppy) | 3.7 | 23.1% | 8.1% |
| R2# | | 3.8 | 13.5% | 27.7% |

Table 3 shows that the performance of the traditional OLED device is not as good as that of the step light-oriented device of the embodiment of the invention.

### Embodiment 3

The multilayer device structure of ITO/HIl/HTL/step photoluminescence layer and ETL/EIL/cathode is constructed. The chemical structure of some organic materials used is as follows:

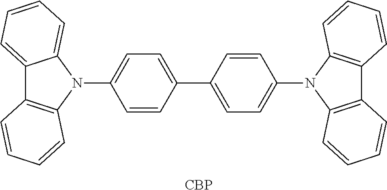 [SMILES: c1ccc2c(c1)c1ccccc1n2-c1ccc(-c2ccc(-n3c4ccccc4c4ccccc43)cc2)cc1 ; "CBP"]

The red light device uses CBP as the host material, and Ir(ppy)₃ as the energy level transition layer. The red light-oriented guest material is obtained from Ir(MDQ)₂(acac), Ir(ppy)₂(bppo), Ir(piq)₃. The properties of the light-oriented guest materials are shown in Table 1.

Analysis of energy level and spectral characteristics:

The triplet energy levels of the host material CBP and the transition layer Ir(ppy)₃ are higher than the T1 energy level of the red light-oriented guest material.

In order to further investigate the energy transfer efficiency of the host material, the energy level transition layer material and the light-oriented guest material in the luminescent layer, the spectral information of the three materials is as follows:

(1) The photoluminescence spectra of the host material CBP (main peak 370 nm) are less than that of the energy level transition layer (main peak 510 nm). The photoluminescence peak wavelength of the transition layer is less than that of the photoluminescence spectrum (510 nm) of the light-oriented guest material (scope of main peak 600 nm-660 nm).

(2) The photoluminescence spectra (main peak is about 470 nm) of the host material CBP and the absorption spectra of the energy level transition layer Ir(ppy)₃ have very good spectral overlap.

(3) The photoluminescence spectra (main peak is about 470 nm) of the host material CBP have very good spectral overlap with the absorption spectra of the red light-oriented guest materials.

(4) The overlapping region between the absorption spectra of the red light-oriented guest materials and host materials (the main peak position is about 470 nm) is larger than that between the absorption spectrum of the light-oriented guest material and the photoluminescence spectrum of the energy level transition layer material Ir(ppy)₃ (the main peak position 510 nm).

(5) The overlapping region between UV absorption spectra of the energy level transition layer and photoluminescence spectra of the host material >0.

Testing of Device Performance:

1. Device 7#-10# is constructed:

ITO/Buffer layer(30 nm/MoO₃(10 nm)/TAPC(30 nm)/CBP: Ir(ppy)₃: red light-oriented guest material, 15 wt. %, 5 wt. %, (30 nm)/TPBi(30 nm)/LiF(1 nm)/Al.

The turn on voltage, maximum external quantum efficiency and efficiency roll-off of the encapsulated OLED devices are tested. The experimental results are shown in Table 4.

2. In order to compare the technical advantages of the device 3#, a comparison device R2 # is designed. The structure of the device as follows: ITO/Buffer layer/MoO₃ (10 nm)/TAPC(30 nm)/CBP:Ir(dmpq)₃, 5 wt. %/TPBi(30 nm)/LiF(1 nm)/cathode.

The comparison R3# is a traditional device structure with a single host-guest doping system. The turn on voltage, maximum external quantum efficiency and efficiency roll-off of the encapsulated OLED devices are tested. The experimental results are also shown in Table 4.

TABLE 4

| | | | Maximum | |
|---|---|---|---|---|
| | | | external | |
| | | Turn on | quantum | |
| Device | Guest | voltage | efficiency | Efficiency |
| number | material | (V) | EQE | roll-off |
| 7# | Ir(ppy)₂(bppo) | 3.3 | 24.7% | 10.6% |
| 8# | Ir(MDQ)₂(acac) | 3.7 | 15.4% | 16.4% |
| 9# | Ir(piq)₃ | 3.9 | 13.5% | 13.8% |
| 10# | Non light-oriented | 3.5 | 8.9% | 19.7% |
| | guest material | | | |
| | Ir(dmpq)₃ | | | |
| R3# | Ir(dmpq)₃ | 4.1 | 7.8% | 20.8% |

Table 4 shows that the performance of the traditional OLED device is not as good as that of the step light-oriented device of the embodiment of the invention.

It is to be understood, however, that even though numerous characteristics and advantages of the present exemplary embodiments have been set forth in the foregoing description, together with details of the structures and functions of the embodiments, the disclosure is illustrative only, and changes may be made in detail, especially in matters of shape, size, and arrangement of parts within the principles of the invention to the full extent indicated by the broad general meaning of the terms where the appended claims are expressed.

What is claimed is:

1. A luminescent device, comprising: a first electrode, a second electrode and at least a luminescent layer arranged between the first electrode and the second electrode, wherein
the luminescent layer comprises at least a host material, at least an energy level transition layer material and at least a guest material;
the energy level transition layer material is a material that receives the energy of the host material and transfers the energy to the guest material.

2. The luminescent device as described in claim 1, wherein the energy level transition layer material directly receives the energy of the host material, and receives the energy lost in the energy transfer process from the host material to the guest material.

3. The luminescent device as described in claim 1, wherein the guest material is a light-oriented luminescent material, and the light-oriented luminescent material is a material with a ratio of light output perpendicular to the direction of the transition dipole moment of the luminescent material, which is larger than the ratio of light output in parallel with the direction of the transition dipole moment of the luminescent material.

4. The luminescent device as described in claim 1, wherein the luminescent layer comprises at least an energy level transition layer material L₁, L₂, . . . Lₙ, n is an integer greater than or equal to 1, and the triplet energy level of the host material is T_{1,H}, the triplet energy level of the energy level transition layer material is T_{1, Ln}, and the triplet energy level of the guest material is T_{1,G}; and following condition should be satisfied:
T_{1,H}, the T_{1,Ln}, the T_{1,G} meet: T_{1,H}>T_{1,Ln}>T_{1,G}.

5. The luminescent device as described in claim 1, wherein the luminescent layer comprises at least an energy level transition layer material L₁, L₂, . . . Lₙ, n is an integer greater than or equal to 1;
when the host material, the energy level transition layer material are selected from the fluorescent material or the thermal delay fluorescent material; the singlet energy level of the host material is S_{1,H}, and the singlet energy level of the energy level transition layer material is S_{1,Ln}, following condition should be satisfied: S_{1,H}>S_{1,Ln};
When the energy level transition layer material, the guest material are selected from the fluorescent material or the thermal delay fluorescent material; the singlet energy level of the energy level transition layer material is S_{1, Ln}, and the singlet energy level of the guest material is S_{1,G}, so that the following condition should be satisfied S_{1,Ln}>S_{1,G};
when the host material, the guest material are selected from the fluorescent material or the thermal delay fluorescent material; the singlet energy level of the host material is S_{1,H}, and the singlet energy level of the guest material is S_{1,G}, so that the following condition should be satisfied S_{1,H}>S_{1,G};
when the host material, the energy level transition layer material, the guest material are selected from the fluorescence material or the thermal delayed fluorescence material, the singlet energy level of the host material is S_{1,H}, and the singlet energy level of the energy level transition layer material is S_{1, Ln}, and the singlet energy level of the guest material is S_{1,G}, so that the following condition should be satisfied S_{1,H}>S_{1,Ln}>S_{1,G}.

6. The luminescent device as described in claim 1, wherein the energy level transition layer material is phosphorescent material.

7. The luminescent device as described in claim 1, wherein the photoluminescence spectrum of the host material is PL_{H}, and the photoluminescence spectrum of the energy level transition layer material is PL_{Ln}, the wavelength of the main emission peak of the PL_{H} is smaller the wavelength of the main emission peak of the PL_{Ln}.

8. The luminescent device as described in claim 1, wherein the photoluminescence spectrum of the host material is PL_{H}, and the photoluminescence spectrum of the guest material is PL_{G}, the wavelength of the main emission peak of the PL_{Ln} is smaller than the wavelength of the main emission peak of the PL_{G}.

9. The luminescent device as described in claim 1, wherein the photoluminescence spectrum of the host material is PL_{H}, and the ultraviolet absorption spectrum of the host material is Abs_{G}, and the photoluminescence spectrum of the energy level transition layer material is PL_{Ln}, and Abs_{G}−PL_{H} denotes a spectral overlap region between Abs_{G} and PL_{H}, and FL_{G}−PL_{Ln} denotes the spectral overlap region between Abs_{G} and PL_{Ln}; the following condition should be satisfied:
Abs_{G}−PL_{H}>Abs_{G}−PL_{Ln}.

10. The luminescent device as described in claim, wherein the ultraviolet absorption spectrum of the energy level transition layer material is Abs_{Ln}, and the photoluminescence spectrum of the host material is PL_{H}, and the Abs_{Ln}−PL_{H} denotes a spectral overlap region between the Abs_{Ln} and the PL_{H}, the following condition should be satisfied: Abs_{Ln}−PL_{H}>0.

11. The luminescent device as described in claim 1, wherein the mass percentage content of the guest material in the luminescent layer is 1%˜20%.

12. The luminescent device as described in claim 1, wherein the mass percentage content of the energy level transition layer material in the luminescent layer is 1%˜30%.

13. The luminescent device as described in claim 12, wherein, when n described energy level transition layer materials are arranged in the luminescent layer, the sum of the mass of the n described energy level transition layer materials does not exceed 50% of the host material.

14. A display device, including a luminescent device as described in claim 1.
